(19) United States
(12) Patent Application Publication
(10) Pub. No.: US 2006/0243315 A1
(43) Pub. Date: Nov. 2, 2006

(54) Gap-filling in electronic assemblies including a TEC structure

(76) Inventors: Gregory M. Chrysler, Chandler, AZ (US); Shriram Ramanathan, Portland, OR (US); Tian-An Chen, Phoenix, AZ (US)

Correspondence Address: KONRAD RAYNES & VICTOR, LLP.;ATTN: INT77, 315 SOUTH BEVERLY DRIVE, SUITE 210, BEVERLY HILLS, CA, 90212, US

(21) Appl. No.: 11/118,814

(22) Filed: Apr. 29, 2005

(51) Int. Cl. H01L 35/34

(52) U.S. Cl. 136/201

(57) ABSTRACT

Embodiments include electronic assemblies and methods for forming electronic assemblies. Certain methods include forming a thermoelectric cooling (TEC) structure on a die, the TEC structure including a plurality of spaced apart TEC legs. A polymer is positioned between the spaced apart TEC legs of the TEC structure. The TEC structure may be positioned between the die and the heat spreader. In one method, a polymer in solid form is positioned on the TEC legs. The polymer in solid form is heated to a temperature sufficient so that a liquid polymer is formed, and the liquid polymer flows between the TEC legs. After being positioned between the TEC legs, the liquid polymer is solidified. Other embodiments are described and claimed.

### RELATED ART

Integrated circuits are generally formed on semiconductor wafers formed from materials such as silicon. The semiconductor wafers are processed to form various electronic devices thereon. The wafers are diced into semiconductor chips, which may then be attached to a package substrate. Such a chip or die may have solder bump contacts on the integrated circuit. The solder bump contacts may extend downward onto contact pads of a substrate. Electronic signals may be provided through the solder bump contacts to and from the integrated circuit. Operation of the integrated circuit generates undesirable heat in the device. Heat is conducted to a surface of the die, and should be conducted away to maintain the temperature of the integrated circuit below a predetermined level for purposes of maintaining functional integrity of the integrated circuit.

One way to conduct heat from an integrated circuit die is through the use of a thermoelectric cooling (TEC) device. The TEC is a structure that is positioned on a device over high heat flux areas to reduce the temperature. In general, a TEC structure may be a solid-state heat pump that acts to transmit heat away from the body to be cooled, and is based on the Peltier Effect, by which a current applied across two dissimilar materials causes a temperature differential to occur. A typical TEC structure may include a series of P-type and N-type doped semiconductor elements (TEC legs or couples) connected in series. The TEC structure may be electrically isolated from the device it cools by an electrically insulative layer.

### BRIEF DESCRIPTION OF THE DRAWINGS

Embodiments are described by way of example, with reference to the accompanying drawings, which are not drawn to scale, wherein:

FIG. 1 is a cross-sectional side view of components of an electronic assembly in accordance with certain embodiments;

FIGS. 2(a)-(d) illustrate a process for forming an assembly in which regions between the legs of a TEC structure are filled with a polymer material, in accordance with certain embodiments; and

FIGS. 3(a)-(d) illustrate a process for forming an assembly in which regions between the legs of a TEC structure are filled with a polymer material, in accordance with certain embodiments;

FIG. 4 is a flow chart describing a process for forming an assembly in which regions between the legs of a TEC structure are filled with a polymer material, in accordance with certain embodiments.

FIG. 5 illustrates one example of a computing environment in which aspects of certain embodiments may be embodied.

### DETAILED DESCRIPTION

There are a variety of ways to place TEC elements onto an electronic assembly including a die. One method is to form the structure through chemical vapor deposition (CVD), metal organic chemical vapor deposition (MOCVD), or other deposition processes. The structure may include a plurality of rows of TEC elements. Another approach is to form the TEC structure on a separate surface and then transfer the TEC structure to the die. Yet another approach is to form the specific TEC structure elements separately and then transfer each element to the die. The various approaches for forming TEC's generally form a TEC structure in which open spaces exist between the elements (such as, for example, semiconductor elements or legs) of the structure.

Having open spaces (filled with air, for example) within the TEC structure may in certain applications be sufficient. However, certain applications place a thermally conductive material on the exposed (hot) surface of the TEC structure. Such a thermally conductive material may include, for example, a thermal grease or solder. If the thermally conductive material flows into the open spaces around the elements, the resultant high thermal conductivity path for heat conduction from the hot side to the cold side may significantly reduce the performance of the TEC structure.

Certain embodiments relate to electronic assembly structures including a TEC structure and methods for forming such assemblies, including filling the open spaces around the elements with a material in order to enable a TEC structure to efficiently transfer heat away from a die.

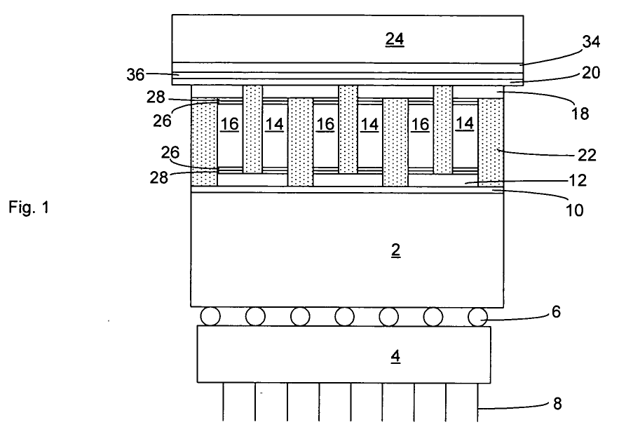

FIG. 1 of the accompanying drawings illustrates components of an electronic assembly according to certain embodiments. The assembly includes a die coupled to a TEC structure on one surface and coupled to a substrate on another surface. The die 2 may be coupled to substrate 4 using a variety of techniques, including, for example, through solder bumps 6. The substrate 4 may be coupled to another device, for example, a motherboard, using a variety of techniques, including, for example, through pins 8. It should be noted that the drawings are not to scale. In addition, the various components may have different widths than those shown in the Figs. For example, the TEC structure and the die, while shown with a similar width in FIG. 1, may have different widths depending on the specific embodiment. In certain embodiments, for example, it may be appropriate to have a TEC structure having a smaller width than the die, due to the thermal properties of the die (e.g. certain regions may generate more or less heat than other regions and the lower heat regions may not need the TEC structure for adequate performance).

The assembly illustrated in FIG. 1 includes TEC legs 14, 16 positioned between electrically conductive regions 12, 18 and between electrically insulative regions 10 and 20. A fill material 22 is positioned within the open regions of the structure. The structure may include a plurality of rows of TEC legs, positioned so that there are open regions between the rows. The electrically insulative region 10 may be formed on the die 2 using a variety of methods. For example, a deposition method such as sputtering may be used to form the electrically insulative region 10 directly on the die 2. In another example, the electrically insulative region 10 may be separately formed and then coupled to the die 2. The electrically insulative regions 10, 20 may be formed from a variety of materials including, but not limited to oxides and nitrides. Examples include silicon oxide, titanium oxide, and silicon nitride. The electrically insulative region 10 may in certain embodiments be formed from the same material as the electrically insulative region 20. The electrically insulative regions 10 and 20 act to electrically insulate the TEC from the die and from a heat spreader body, and may be formed from a material that is electrically insulative but that is capable of conducting heat away from the die. In certain embodiments, the electrically insulative regions 10, 20 are formed to be approximately 1000 Å thick, the TEC legs 14,16 are formed to be approximately 100 μm thick, and the die 2 is formed to be approximately 750 μm thick. TEC legs 14 and 16 are preferably formed from a doped semiconductor material, with one of legs 14 and 16 being P-type and the other being N-type. One P-type leg and one N-type leg make up one thermoelectric couple, with the TEC illustrated in FIG. 1 showing a row with three thermoelectric couples. The electrically conductive regions 12, 18 may be formed using a variety of methods, for example, sputtering, and may be formed from a variety of materials, for example, copper. The TEC legs 14, 16 are coupled to the electrically conducive regions 12 and 18 through solder layers 28 and barrier layers 26 at both ends of the TEC legs 14, 16.

A body 24 such as a heat spreader may be positioned on the TEC structure on electrically insulative region 20. Layers 34 and 36 are positioned between the body 24 and the electrically insulative region 20. Layer 34 may be a material such as a solder for coupling the layers together. Layer 36 generally acts to ensure adequate adhesion between the layers, and may include one or more metal layers. In one embodiment, the layer 36 includes layers of Ti, Ti—Ni, and Au. Heat is transferred through the electrically insulative region 20 to the heat spreader 24. A low thermal conductivity material 22 is positioned within the open regions of the structure adjacent to the TEC legs 14 and 16, between the electrically insulative region 10 and the electrically conductive region 18, and between the electrically insulative region 20 and the electrically conductive region 12.

In accordance with certain embodiments, a number of processes may be used to fill the open regions in the TEC structure with a low thermal conductivity material. Such processes may include one or more of spin-on, reflow, and capillary force methods. Some processes may require a post application operation to clean exposed surfaces of any excess material. Capillary force methods generally act to draw the material (for example, a polymer), into the open regions of the TEC structure. There are factors relating to reliability and processing that may influence the exact material chosen as the low thermal conductivity material. Reliability factors may include, for example, low thermal conductivity, good adhesion to interfaces, and good moisture resistivity. Process related factors include, for example, proper viscosity to fill gaps, stability during processing operations, and ability to flow according to capillary action. Certain embodiments use a polymer material (for example, a filled or unfilled polymer) that can be cured to cross-link the polymer and form a hard encapsulating material.

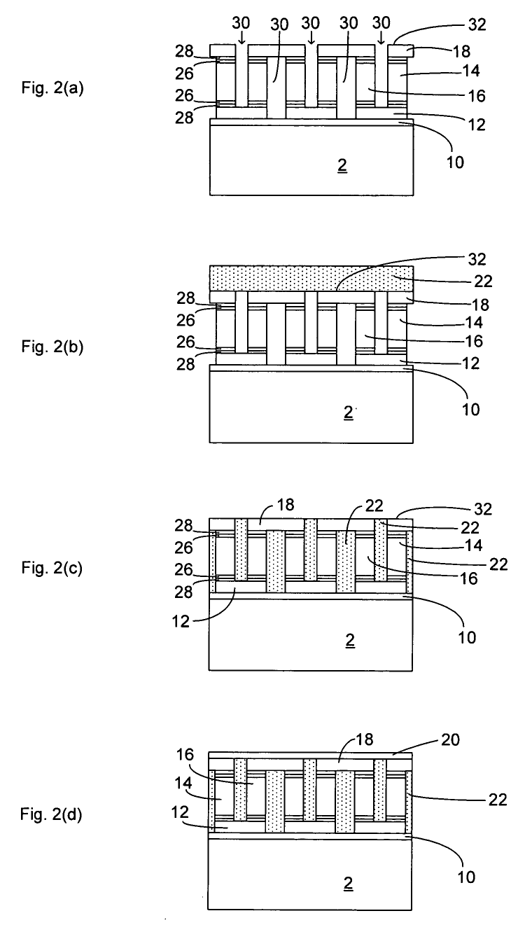

FIGS. 2(a)-2(d) illustrate a process for forming an assembly in which the open regions of a TEC structure are filled with a polymer material. FIG. 2(a) shows a portion of the assembly, including TEC legs 14 and 16 positioned between electrically conductive regions 12 and 18. Between and adjacent to the TEC legs 14 and 16 are open regions 30 into which the low thermal conductivity material (for example, a polymer) will be placed.

FIG. 2(b) shows a polymer 22 positioned on an upper surface 32 of the electrically conductive regions 18. The polymer 22 is preferably in solid form at room temperature, although a liquid may be used in certain embodiments. The polymer 22 is then heated to a temperature above its melting point. The molten polymer 22 then flows into the open regions 30 between and adjacent to the TEC legs 14 and 16 by capillary action. In certain embodiments, the open region space between the TEC legs (and between rows of TEC legs) is in the range of about 25 μm to about 50 μm. An appropriately chosen polymer, along with proper surface treatment of the top surface 32, act to ensure that the polymer 22 does not adhere to the top surface 32 when melted, but instead flows into the open regions 30 of the TEC structure.

FIG. 2(c) shows the polymer 22 in the open regions 30 of the TEC structure. In certain embodiments, a cleaning operation may be performed to clean any residue from the top surface 32 of the electrically conductive regions 18. As seen in FIG. 2(d), electrically insulative layer 20 is then positioned on the electrically conductive regions 18. Heat spreader 24 is then positioned on the insulative layer 20 to complete the assembly.

The polymer 22 may be formed from a variety of materials. As described above, in certain embodiments, the polymer 22 may be solid at room temperature. Upon heating to a relatively low temperature, for example, about 50-60° C. in certain embodiments, the polymer may melt and flow into the openings in the TEC structure.

In certain embodiments, the polymer may be an epoxy type with anhydride, phenol or amine resin hardener. In other embodiments, the polymer may be a thermoplastic polymer with or without a filler such as silica. The thermal conductivity of epoxy and other resins are typically approximately 0.2-0.3 W/m-K, and the thermal conductivity of silica is normally about 1.5 W/m-K. The overall thermal conductivity of the polymer film with or without filler are low and can be tuned for the specific application. The physical properties of the polymer film such as the coefficient of thermal expansion (CTE), glass transition temperature (Tg), thermal stability, and adhesion can also be fine tuned to meet the specific application requirement. Certain applications may, for example, include modules having different spacings therebetween or different strength requirements. In certain embodiments, it is desired to have a polymer having a coefficient of thermal expansion that is approximately 30-60 ppm and a glass transition temperature of at least 100° C., and a thermal stability that shows no degradation below approximately 300° C.

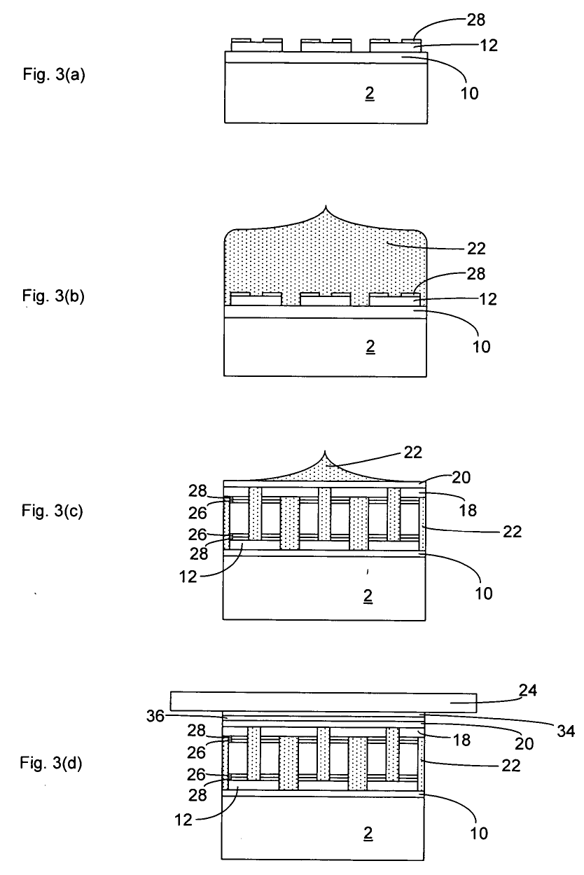

FIGS. 3(a)- 3(d) illustrate a method for forming an assembly in accordance with certain embodiments. As seen in FIG. 3(a), an assembly including a portion of a TEC structure is formed on the die 2. The assembly includes electrically insulative layer 10 on the die 2. Electrically conductive regions 12 are formed on the electrically insulative layer 10. Solder regions 28 are formed on the electrically conductive regions 12. The TEC legs are coupled to the solder regions 28 in a later operation.

FIG. 3(b) shows a liquid polymer 22 formed on the assembly, over the electrically insulative layer 10, the electrically conductive regions 12, and the solder regions 28. The rest of the TEC structure will be placed into contact with the solder regions 28 through the liquid polymer 22.

FIG. 3(c) shows the TEC legs 14, 16 positioned on the solder regions 28 through the liquid polymer 22. The TEC legs 14, 16 are coupled to electrically conductive regions 18. The electrically conductive regions 18 are coupled to the electrically insulative layer 20. As seen in FIG. 3(c) the liquid polymer fills spaces between the TEC legs 14, 16 and between the electrically conductive regions 12 and the electrically insulative layer 20, and between the electrically conductive regions 18 and the electrically insulative layer 10. Any excess polymer 22 may be cleaned from the upper surface 32 of the electrically conductive regions 18.

As seen in FIG. 3(d), an electrically insulative layer 20 and a body such as heat spreader 24 may be coupled to the assembly to transfer heat from the TEC structure. The heat spreader 24 may be coupled to the electrically insulative layer 20 through a solder layer 34. The heat spreader may, in certain embodiments, be about 2.5 mm thick. The heat spreader may also have a variety of geometries, depending on various requirements such as the available space.

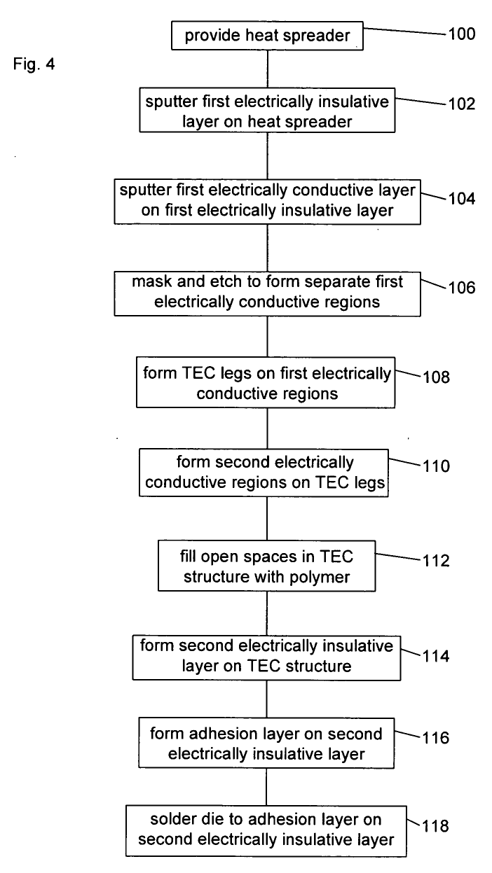

FIG. 4 is a flowchart describing certain embodiments including a method for forming an assembly. Certain aspects are similar to those described above. In the method the TEC structure is coupled to the heat spreader and then the die is coupled to the TEC structure and heat spreader.

Block 100 is providing a heat spreader. Block 102 is forming a first electrically insulative layer on the heat spreader using a method such as, for example, sputtering. Block 104 is forming a first electrically conductive layer on the electrically insulative layer using a method such as, for example, sputtering. Block 106 is performing a masking and etching process on the electrically conductive layer to form separate first electrically conductive regions. Block 108 is forming the TEC legs on the electrically conductive regions. Layers such as barrier and solder layers as described above, may be present. Block 110 is forming second electrically conductive regions on the TEC legs. Block 112 is filling the open spaces in the TEC structure (such as between the TEC legs) with a low thermal conductivity material using a method such as those discussed above. Block 114 is forming a second electrically insulative layer on the TEC structure, so that the first and second electrically conductive regions, the TEC legs, and the low thermal conductivity material are positioned between the first and second electrically insulative layers. The second electrically insulative layer may be formed using a method such as, for example, sputtering. Block 116 is forming an adhesion layer (such as the layer 36 discussed earlier, which may include multiple sub-layers) on the second insulative layer. Block 118 is soldering the die to the adhesion layer in order couple the die to the rest of the assembly.

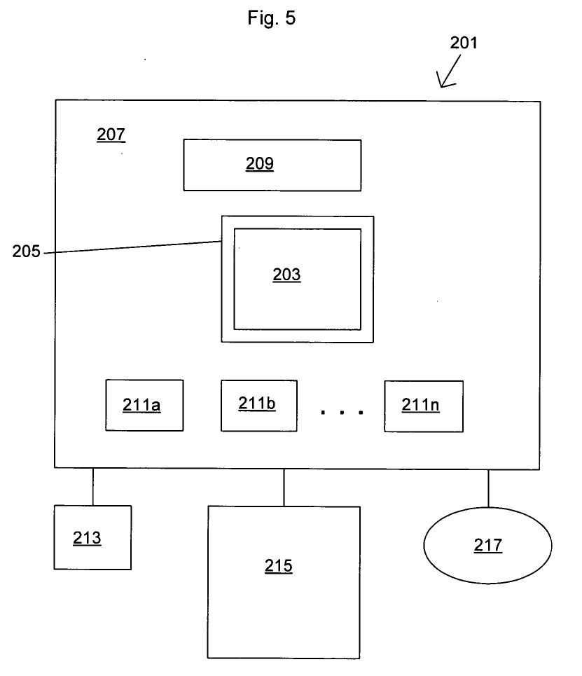

FIG. 5 illustrates one example of a computing environment in which aspects of described embodiments may be embodied. The computing environment includes a computer 201 including at least one central processing unit (CPU) 203. The CPU 203, also referred to as a microprocessor, may be attached to an integrated circuit package 205, which is then coupled to a printed circuit board 207, which in this embodiment, is a motherboard. The integrated circuit package 205 is an example of an electronic assembly in accordance with the embodiments discussed above and shown in FIGS. 1-4.

The computer 201 further may further include memory 209 and one or more controllers 211a, 211b . . . 211n, which are also disposed on the motherboard 207. The motherboard 207 may be a single layer or multi-layered board which has a plurality of conductive lines that provide communication between the circuits in the package 205 and other components mounted to the board 207. Alternatively, one or more of the CPU 203, memory 209 and controllers 21la, 211b . . . 211n may be disposed on other cards such as daughter cards or expansion cards. The CPU 203, memory 209 and controllers 211a, 211b . . . 211n may each be seated in individual sockets or may be connected directly to a printed circuit board. A display 215 may also be included.

Any suitable operating system and various applications execute on the CPU 203 and reside in the memory 209. The content residing in memory 209 may be cached in accordance with known caching techniques. Programs and data in memory 209 may be swapped into storage 213 as part of memory management operations. The computer 201 may comprise any suitable computing device, such as a mainframe, server, personal computer, workstation, laptop, handheld computer, telephony device, network appliance, virtualization device, storage controller, network controller, etc.

The controllers 211a, 211b . . . 211n may include a system controller, peripheral controller, memory controller, hub controller, I/O bus controller, video controller, network controller, storage controller, etc. For example, a storage controller can control the reading of data from and the writing of data to the storage 213 in accordance with a storage protocol layer. The storage protocol of the layer may be any of a number of known storage protocols. Data being written to or read from the storage 213 may be cached in accordance with known caching techniques. A network controller can include one or more protocol layers to send and receive network packets to and from remote devices over a network 217. The network 217 may comprise a Local Area Network (LAN), the Internet, a Wide Area Network (WAN), Storage Area Network (SAN), etc. Embodiments may be configured to transmit data over a wireless network or connection. In certain embodiments, the network controller and various protocol layers may employ the Ethernet protocol over unshielded twisted pair cable, token ring protocol, Fibre Channel protocol, etc., or any other suitable network communication protocol.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

What is claimed:

1. A method of forming an electronic assembly, comprising:
forming a thermoelectric cooling (TEC) structure on a die, the TEC structure including a plurality of spaced apart TEC legs; and
positioning a material comprising a polymer between the spaced apart TEC legs of the TEC structure.

2. A method according to claim 1, further comprising coupling a heat spreader to the TEC structure so that the TEC structure is positioned between the die and the heat spreader.

3. A method according to claim 1, wherein the positioning a polymer between the spaced apart TEC legs includes using capillary action to position the polymer between the spaced apart TEC legs.

4. A method according to claim 1, wherein the positioning a material comprising a polymer between the spaced apart TEC legs includes using a spin-on process to position the material between the spaced apart TEC legs.

5. A method according to claim 1, wherein the positioning a material comprising a polymer between the spaced apart TEC legs includes placing a solid polymer on the TEC legs and heating the solid polymer so that a liquid polymer is formed, and positioning the liquid polymer between the spaced apart TEC legs.

6. A method according to claim 5, further comprising solidifying the liquid polymer between the spaced apart TEC legs.

7. A method according to claim 1, wherein the positioning a material comprising a polymer between the spaced apart TEC legs includes placing a liquid polymer on the die and then placing the TEC legs into the liquid polymer.

8. A method according to claim 7, further comprising, prior to placing the liquid polymer on the die, forming an electrically insulative layer on the die and forming a plurality of electrically conductive pad regions on the insulative layer.

9. A method according to claim 8, further comprising positioning the TEC legs so that an end of each the TEC legs is positioned on one of the electrically conductive pad regions.

10. A method according to claim 9, further comprising solidifying the liquid polymer.

11. A method of forming an electronic assembly including a die and a thermoelectric cooling (TEC) structure including a plurality of TEC legs, the method comprising:
forming an electrically insulative layer on the die;
forming a plurality of spaced apart electrically conductive pads on the electrically insulative layer;
positioning the TEC legs on the spaced apart electrically conductive pads;
positioning a material comprising a polymer in solid form on the TEC legs on the spaced apart electrically conductive pads;
heating the polymer in solid form to a temperature sufficient so that a liquid polymer is formed;
positioning the liquid polymer between the TEC legs; and
after the positioning the liquid polymer between the TEC legs, solidifying the polymer.

12. A method according to claim 11, wherein the positioning the liquid polymer between the TEC legs includes using capillary action to position the polymer between the TEC legs.

13. A method according to claim 11, further comprising positioning a heat spreader in thermal contact with the TEC structure, wherein the TEC structure is positioned between the heat spreader and the die.

14. A method of forming an electronic assembly including a die and a thermoelectric cooling (TEC) structure including a plurality of TEC legs, the method comprising:
forming an electrically insulative layer on the die;
forming a plurality of spaced apart electrically conductive pads on the electrically insulative layer;
forming a material comprising a liquid polymer on the electrically conductive pads and the electrically insulative layer;
placing the TEC legs on the electrically conductive pads by passing the TEC legs through the liquid polymer; and
solidifying the liquid polymer.

15. A method according to claim 14, further comprising positioning a heat spreader on TEC structure, wherein the TEC structure and the polymer are positioned between the die and the heat spreader.

16. A method of forming an electronic assembly, comprising:
forming a thermoelectric cooling (TEC) structure on a heat spreader, the TEC structure including a plurality of spaced apart TEC legs;
positioning a material comprising a polymer between the spaced apart TEC legs of the TEC structure; and
coupling a die to the TEC structure and the heat spreader, so that the TEC structure is positioned between the heat spreader and the die.

17. A method according to claim 16, wherein the positioning the material comprising a polymer between the TEC legs includes using capillary action to position the polymer between the TEC legs.

18. A method according to claim 16, wherein the positioning a material comprising a polymer between the spaced apart TEC legs includes placing a solid polymer on the TEC legs and heating the solid polymer so that a liquid polymer is formed, and positioning the liquid polymer between the spaced apart TEC legs.

19. A method according to claim 16, wherein the positioning a material comprising a polymer between the spaced apart TEC legs includes placing a liquid polymer on the heat spreader and then placing the TEC legs into the liquid polymer.

20. A method according to claim 19, further comprising, prior to placing the liquid polymer on the heat spreader, forming an electrically insulative layer on the heat spreader and forming a plurality of electrically conductive pad regions on the insulative layer.

21. A method according to claim 20, further comprising positioning the TEC legs so that an end of each the TEC legs is positioned on one of the electrically conductive pad regions.

22. An electronic assembly comprising:
a die;
a first electrically insulative layer on the die;
a thermoelectric cooling (TEC) structure including a plurality of TEC legs extending between electrically conductive pads;
a material comprising a polymer positioned between adjacent TEC legs;
a second electrically insulative layer on the TEC structure; and
a heat spreader positioned on the second insulative layer, wherein the second insulative layer is positioned between the heat spreader and the TEC structure.

23. An electronic assembly according to claim 22, further comprising a substrate to which the die is coupled, wherein the die is positioned between the substrate and the first electrically insulative layer.

24. An electronic assembly according to claim 22, wherein the adjacent TEC legs are spaced 25 μm to 50 μm apart from each other.
